(19) United States
(12) Patent Application Publication
(10) Pub. No.: US 2007/0269747 A1
(43) Pub. Date: Nov. 22, 2007

(54) Lithography Technique Using Silicone Molds

(76) Inventors: Maneesh Bahadur, Midland, MI (US); Wei Chen, Midland, MI (US); John Albaugh, Freeland, MI (US); Brian Harkness, Midland, MI (US); James Tonge, Sanford, MI (US)

Correspondence Address: DOW CORNING CORPORATION CO1232, 2200 W. SALZBURG ROAD, P.O. BOX 994, MIDLAND, MI, 48686-0994, US

(21) Appl. No.: 11/659,989

(22) PCT Filed: Aug. 31, 2005
(86) PCT No.: PCT/US05/31150

§ 371 Date: Feb. 12, 2007

Related U.S. Application Data
(60) Provisional application No. 60/609,425, filed on Sep. 13, 2004.

(51) Int. Cl. G03F 7/00; G03F 7/004; G03F 7/027

(52) U.S. Cl. 430/319; 430/323

(57) ABSTRACT

A method includes the steps of: A) filling a silicone mold having a patterned surface with a curable (meth)acrylate formulation, B) curing the curable (meth)acrylate formulation to form a patterned feature, C) separating the silicone mold and the patterned feature, optionally D) etching the patterned feature, and optionally E) repeating steps A) to D) reusing the silicone mold. The curable (meth)acrylate formulation contains a fluorofunctional (meth)acrylate, a (meth)acrylate, and a photoinitiator.

### CROSS REFERENCE

None.

### TECHNICAL FIELD

This invention relates to a method using a curable (meth)acrylate formulation with a silicone mold. The method finds use in various lithography techniques.

### Problems to be Solved

There is a need to improve lithography techniques to provide sufficient mold release and provide multiple and accurate patterned features from high aspect ratio features on silicone molds. There is a need to provide a method for molding high aspect ratio features from silicone molds with curable (meth)acrylate formulations.

### Means for Solving the Problems

Curable (meth)acrylate formulations may be cured with high resolution of the mold pattern by using a UV cure mechanism or a combination of UV and thermal cure mechanisms. Mold release may be improved by using a fluorofunctional (meth)acrylate.

### SUMMARY

This invention relates to method a comprising:

A) filling a silicone mold having a patterned surface with a curable (meth)acrylate formulation;

B) curing the curable (meth)acrylate formulation to form a patterned feature;

C) separating the silicone mold and the patterned feature;

optionally D) etching the patterned feature; and

optionally E) repeating steps A) to D) reusing the silicone mold.

### DETAILED DESCRIPTION

All amounts, ratios, and percentages are by weight unless otherwise indicated. The following is a list of definitions, as used herein.

Definitions

When introducing elements of this invention, the articles “a”, “an”, and “the” mean that there are one or more of the elements.

The abbreviations have the following meanings: “cP” means centipoise, “PDMS” means polydimethylsiloxane, and “UV” means ultra-violet.

“(Meth)acrylate means a reactant that does not contain silicon atoms and that does contain at least one group of the formula: 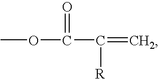
where R is a hydrogen atom or a methyl group.
Curable (Meth)acrylate Formulation

The curable (meth)acrylate formulation suitable for use in this invention is curable by exposure to UV radiation, heat, or combinations thereof. The viscosity of the curable (meth)acrylate formulation may be selected depending on the desired feature size to be formed by the method of this invention. For example, when viscosity is greater than 200 cP, resolution may be 100 micrometers or more. When viscosity is 200 cP or less, resolution may be up 30 micrometers. When viscosity is less than 10 cP, alternatively 1 to 10 cP, resolution may be 100 nanometers (nm) to 10 micrometers, alternatively 5 to 10 micrometers.

The curable (meth)acrylate formulation comprises: (a) a fluorofunctional (meth) acryl ate or a combination of a fluorofunctional (meth)acrylate and a (meth)acrylate and (b) a photoinitiator. Alternatively, the curable (meth)acrylate formulation comprises: (a) a (meth)acrylate, a fluorofunctional (meth)acrylate, or a combination thereof and (b) a photoinitiator. The curable (meth)acrylate formulation may further comprise one or more optional components selected from the group consisting of (c) an antioxidant, (d) a fluorescent dye, (e) a reactive diluent, (f) a light stabilizer, (g) a photosensitizer, (h) a wetting agent, (i) a silane, and (j) a UV absorber.

Without wishing to be bound by theory, it is thought that fluorofunctional (meth)acrylates do not self associate to the extent that polar molecules do; therefore, a fluorofunctional (meth)acrylate may help retain low viscosity of the curable (meth)acrylate formulation when the fluorofunctional (meth)acrylate is added to the curable (meth)acrylate formulation. Fluorofunctional (meth)acrylates may also facilitate mold release.

Component (a) (Meth)acrylate and Fluorofunctional (meth)acrylate

The (meth)acrylate may be monofunctional or multifunctional, or a combination thereof. Component (a) may comprise a monofunctional (meth)acrylate, a difunctional (meth)acrylate, a trifunctional (meth)acrylate, a tetrafunctional (meth)acrylate, a pentafunctional (meth)acrylate, or a combination thereof. Alternatively, component (a) may comprise a monofunctional (meth)acrylate, a difunctional (meth)acrylate, a trifunctional (meth)acrylate, or a combination thereof. The (meth)acrylate is free of fluorine atoms. The fluorofunctional (meth)acrylate may be monofunctional or multifunctional, or a combination thereof. The fluorofunctional (meth)acrylate comprises at least one fluorine atom. The fluorofunctional (meth)acrylate may comprise a monofunctional fluorofunctional (meth)acrylate, a difunctional fluorofunctional (meth)acrylate, a trifunctional fluorofunctional (meth)acrylate, a tetrafunctional fluorofunctional (meth)acrylate, a pentafunctional fluorofunctional (meth)acrylate, or a combination thereof. Component (a) may comprise at least one fluorofunctional (meth)acrylate.

Component (a) may comprise one or more components having the general formula: 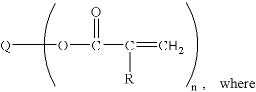
Q is a hydrogen atom or an organic group, each R is independently a hydrogen atom or a methyl group, and the subscript n represents the degree of functionality. For example, when n is 1, Q is monofunctional. When n is 2, Q is difunctional. When n is 3, Q is trifunctional. When n is 4, Q is tetrafunctional. When n is 5, Q is pentafunctional. When n is 6, Q is hexafunctional. When Q is a hydrogen atom or an organic group free of fluorine atoms, the component is a (meth)acrylate. When Q is an organic group containing at least one fluorine atom, the component is a fluorofunctional (meth)acrylate.

Monofunctional (meth)acrylates may have the general formula: 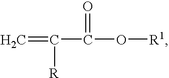
where R is a hydrogen atom or a methyl group and R¹ is a monovalent organic group free of fluorine atoms. Monovalent organic groups for R¹ may be linear, branched, or cyclic. Examples of monovalent organic groups for R¹ include, but are not limited to, monovalent hydrocarbon groups. Monovalent hydrocarbon groups include, but are not limited to, alkyl groups exemplified by methyl, ethyl, propyl, butyl, pentyl, hexyl, heptyl, and ethylhexyl; alkenyl groups exemplified by vinyl and allyl; cyclic hydrocarbon groups exemplified by cyclopentyl, cyclohexyl, and isobornyl. Examples of monovalent organic groups for R¹ further include, but are not limited to, monovalent hydrocarbonoxy functional organic groups such as alkoxy groups exemplified by methoxy, ethoxy, propoxy, and butoxy; alkoxyalkyl such as methoxymethyl, ethoxymethyl, methoxyethyl, and ethoxyethyl; alkoxyalkoxyalkyl such as methoxymethoxymethyl, ethoxyethoxymethyl, methoxymethoxyethyl, and ethoxyethoxyethyl.

Examples of monofunctional (meth)acrylates include, but are not limited to, 2(2-ethoxyethoxy)ethyl acrylate, 2-acryloylethyl-2-hydroxyethyl-o-phthalate, 2-ethoxyethoxyethyl acrylate, 2-ethoxyethyl acrylate, 2-ethoxyethylmethacrylate, 2-ethylhexyl methacrylate, 2-hydroxyethyl acrylate, 2-hydroxyethyl methacrylate, 2-hydroxypropyl acrylate, 2-hydroxypropyl methacrylate, 2-methoxyethyl acrylate, 2-phenoxyethyl acrylate, 4-hydroxybutyl acrylate, acrylic acid, alkoxylated lauryl acrylate, alkoxylated phenol acrylate, alkoxylated tetrahydrofurfuryl acrylate, allyl methacrylate, benzyl acrylate, benzyl methacrylate, beta carboxy ethyl acrylate, butyl diglycol methacrylate, caprolactone acrylate, cetyl acrylate, cyclic trimethylolpropane formal acrylate, cyclohexyl acrylate, cyclohexyl methacrylate, cyclohexylmethacrylate, dicyclopentadienyl methacrylate, diethylaminoethyl methacrylate, dimethyl aminoethyl acrylate, dimethyl aminoethyl methacrylate, dimethyl aminoethyl methacrylate methylchloride salt, E07 ethyl capped methacrylate, epoxy acrylate, ethoxyethyl methacrylate, ethoxylated (10) hydroxyethyl methacrylate, ethoxylated (2) hydroxyethyl methacrylate, ethoxylated (5) hydroxyethyl methacrylate, ethoxylated phenol acrylate, ethyl methacrylate, ethyl triglycol methacrylate, glycidyl methacrylate, hydroxyethyl acrylate, isobornyl acrylate, isobornyl methacrylate, isobutyl acrylate, isobutyl methacrylate, isodecyl acrylate, isooctyl acrylate, lauryl acrylate, lauryl methacrylate, lauryl tridecyl acrylate, methacrylic acid, methacrylonitrile, methoxy polyethylene glycol (350) monoacrylate E06, methyl methacrylate, n-butyl methacrylate, octyl decyl acrylate, polypropylene glycol monomethacrylate, propoxylated (2) allyl methacrylate, stearyl acrylate, stearyl methacrylate, tert-butyl amino methacrylate, tert-butyl acrylate, tert-butyl methacrylate, tetrahydrofurfuryl acrylate, tetrahydrofurfuryl methacrylate, tetrahydrofuryl acrylate, tetrahydrofuryl methacrylate, tetrahydrogenfuranmethacrylate, tridecyl acrylate, tridecyl methacrylate, trimethylcyclohexylmethacrylate, urethane acrylate, and combinations thereof.

Difunctional (meth)acrylates may have the general formula: 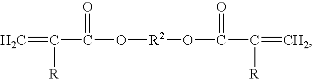
where each R is independently a hydrogen atom or a methyl group and R² is a divalent organic group free of fluorine atoms. Examples of divalent organic groups for R² include, but are not limited to, divalent hydrocarbon groups such as alkylene groups exemplified by methylene, ethylene, propylene, butylene, pentylene, hexylene, heptylene, and ethylhexylene. Examples of divalent organic groups for R² further include, but are not limited to, divalent hydrocarbonoxy functional organic groups such as groups of the formula:
—R′ₐ—O—(R″_{b}—O)_{c}—R′″_{d}13 ,
where the subscript a is at least 1, b is 0 or greater, c is 0 or greater, d is at least 1; and R′, R″ and R′″ are each independently a divalent hydrocarbon group such as those described above.

Examples of difunctional (meth)acrylates include, but are not limited to, 1,12-dodecandiol dimethacrylate, 1,3-butandiol dimethacrylate, 1,3-butylene glycol diacrylate, 1,3-butylene glycol dimethacrylate, 1,4-butanediol diacrylate, 1,4 butanediol dimethacrylate, 1,6-hexanediol diacrylate, 1,6-hexanediol dimethacrylate, alkoxylated aliphatic diacrylate, aliphatic dimethacrylate, bisphenol A diacrylate, bisphenol A ethoxylate dimethacrylate, butanediol dimethacrylate, diethylene glycol diacrylate, diethylene glycol dimethacrylate, dipropylene glycol diacrylate, dipropylene glycol dimethacrylate, ethoxylated bisphenol-A diacrylate, ethylene glycol dimethacylate, neopentyl glycol diacrylate, polyethylene glycol 200 diacrylate, polyethylene glycol 200 dimethacrylate, polypropylene glycol 400 dimethacrylate, propoxylated (2) neopentyl glycol diacrylate, tetraethylene glycol diacrylate, tetraethylene glycol dimethacrylate, tricyclodecane dimethanol diacrylate, triethylene glycol dimethacrylate, tripropylene glycol diacrylate, and combinations thereof.

Trifunctional (meth)acrylates may have the general formula: 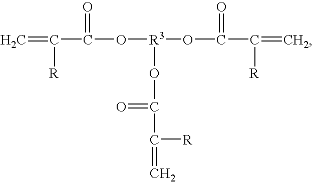
where each R is independently a hydrogen atom or a methyl group and R³ is a trivalent organic group free of fluorine atoms. Examples of trivalent organic groups for R³ include, but are not limited to, trivalent hydrocarbon groups such as ethylyne, propylyne, and butylyne. Examples of trivalent organic groups for R³ further include, but are not limited to, hydrocarbonoxy functional groups such as R¹—C—[R′ₐ—O—(R″_{b}—O)_{c}—R′″_{d}]—₃, where R¹, R′, R″, R′″, a, b, c, and d are as described above.

Examples of trifunctional (meth)acrylates include, but are not limited to, ethoxylated trimethylol propane triacrylate, glycelyl propoxy triacrylate, pentaerythritol triacrylate, propoxylated glycerol triacrylate, propoxylated trimethylolpropane triacrylate, triacrylate ester, trimethacrylate ester, trimethylol propane triacrylate, trimethylol propane trimethacrylate, trimethylolpropane ethoxy triacrylate, and combinations thereof.

Other multifunctional (meth)acrylates having more than 3 (meth)acrylate containing groups may be used. Examples of such multifunctional (meth)acrylates include, but are not limited to, tetrafunctional acrylate, acrylate ester of pentaerythritol, pentaerythritol tetraacrylate, dipentaerythritol pentaacrylate, ditrimethylolpropane tetraacrylate, ethoxylated pentaerythritol tetraacrylate, caprolactone modified dipentaerythritol hexaacrylate, caprolactone modified dipentaerythritol hexamethacrylate, and combinations thereof.

Monofunctional, fluorofunctional (meth)acrylates may have the general formula: 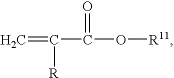
where R is a hydrogen atom or a methyl group and R¹¹ is a monovalent organic group containing at least one fluorine atom. Examples of suitable monovalent organic groups for R¹¹ include, but are not limited to, fluorinated monovalent hydrocarbon groups such as fluorinated alkyl groups exemplified by heptadecafluorodecyl, heptafluoropentyl, nonafluorohexyl, octafluoropentyl, pentafluorobutyl, tetrafluopropyl, trifluoroethyl, and trifluoropropyl. Alternatively, R¹¹ may be octafluoropentyl or trifluoroethyl.

Examples of suitable monofunctional, fluorofunctional (meth)acrylates include, but are not limited to, heptadecafluorodecyl acrylate, octafluoropentyl acrylate, octafluoropentyl methacrylate, tetrafluopropyl acrylate, trifluoroethyl acrylate, trifluoroethyl methacrylate, and combinations thereof.

Difunctional, fluorofunctional (meth)acrylates may have the general formula: 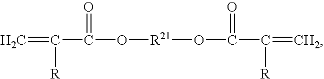
where each R is independently a hydrogen atom or a methyl group and R²¹ is a divalent organic group containing at least one fluorine atom. Examples of suitable divalent organic groups for R²¹ include, but are not limited to, fluorinated divalent hydrocarbon groups such as fluorinated alkylene groups exemplified by heptadecafluorodecylene, heptafluoropentylene, nonafluorohexylene, octafluoropentylenee, pentafluorobutylene, tetrafluopropylene, trifluoroethylene, and trifluoropropylene.

Trifunctional, fluorofunctional (meth)acrylates may have the general formula: 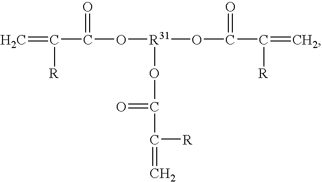
where each R is independently a hydrogen atom or a methyl group and R³¹ is a trivalent organic group containing at least one fluorine atom. Examples of suitable trivalent organic groups for R³¹ include, but are not limited to, fluorinated trivalent hydrocarbon groups such as fluorinated alkylyne groups exemplified by heptadecafluorodecylyne, heptafluoropentylyne, nonafluorohexylyne, octafluoropentylyne, pentafluorobutylyne, tetrafluopropylyne, trifluoroethylyne, and trifluoropropylyne.

Suitable fluorofunctional (meth)acrylates and (meth)acrylates for component (a) are known in the art and commercially available from, for example, Osaka Organic Chemical Industry LTD; Rbhm Monomers of Europe; Sartomer Company, Inc., of Lancaster, Pa., U.S.A.; and The UCB Group of Belgium.

The amount of component (a) may range from 90 to 99.5% based on the weight of the curable (meth)acrylate formulation. The amount of (meth)acrylate may range from 0 to 75%, based on the weight of the curable (meth)acrylate formulation. The amount of fluorofunctional (meth)acrylate may range from 0 to 99.5%, alternatively 25 to 99.5%, alternatively 20 to 90%, based on the weight of the curable (meth)acrylate formulation. The amount of fluorofunctional (meth)acrylate in the curable (meth)acrylate formulation may be sufficient to provide at least 0.5% fluorine at the surface of a feature prepared by molding the curable (meth)acrylate formulation.

Component (b) Photoinitiator

Component (b) is a photoinitiator. The amount of component (b) is sufficient to promote cure of the curable (meth)acrylate formulation and depends on the type of photoinitiator selected and the ingredients in component (a). However, the amount of component (b) may range from 0.5 to 10% based on the weight of the curable (meth)acrylate formulation. When a free radical photoinitiator is used, the amount may range from 0.01 to 5%, alternatively 0.1 to 2%, based on the total weight of the curable (meth)acrylate formulation.

Component (b) may comprise a free radical photoinitiator exemplified by benzoins (e.g., benzoin alkyl ethers), benzophenone and its derivatives (e.g., 4,4′-dimethyl-amino-benzophenone), acetophenones (e.g., dialkoxyacetophenones, dichloroacetophenones, and trichloroacetophenones), benzils (e.g., benzil ketals), quinones, and O-acylated-.alpha.-oximinoketones. The free radical photoinitiator may comprise a compound represented by the following structural formula: 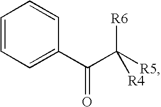
where R4 is a hydrogen atom, an alkoxy group, a substituted alkoxy group, or a halogen atom; R5 is a hydroxyl group, an alkoxy group, a substituted alkoxy group, or a halogen atom; and R6 is a hydrogen atom, an alkyl group, a substituted alkyl group, an aryl group, a substituted aryl group, or a halogen atom. Alternatively, R4 may be a methyl group, R5 may be a hydroxyl group, and R6 may be a methyl group or a phenyl group. Alternatively, R4 is a hydrogen atom, R5 is an alkoxy group, and R6 is a phenyl group. Alternatively, R4 and R5 are each independently an alkoxy group and R6 is a hydrogen atom. Alternatively, R4 and R5 are each a chlorine atom and R6 is a chlorine atom or a hydrogen atom.

Suitable photoinitiators are known in the art and are commercially available. Examples of the photoinitiator include, but are not limited to, alpha-hydroxy ketone; phenylglyoxylate; benzildimethyl-ketal; alpha-aminoketone; mono acyl phosphine; bis acyl phosphine; benzoin ether; benzoin isobutyl ether; benzoin isopropyl ether; benzophenone; benzoylbenzoic acid; methyl benzoylbenzoate; 4-benzoyl-4′-methyldiphenyl sulfide; benzylmethylketal; 2-n-butoxyethyl-4-dimethylaminobenzoate; 2-chlorothioxanthone; 2,4-diethylthioxanthanone; 1-hydroxy-cyclohexyl-phenyl-ketone (Ciba® IRGACURE® 184 from Ciba Specialty Chemicals, Inc. of Tarrytown, N.Y. 10591, U.S.A.); methylbenzoylformate; phenyl bis(2,4,6-trimethyl benzoyl)-phosphine oxide (Ciba® IRGACURE® 819 also from Ciba Specialty Chemicals, Inc.); a combination of bis(2,6-dimethoxybenzoyl)-2,4,4-trimethyl-pentylphosphineoxide and 1-hydroxy-cyclohexyl-phenyl-ketone (Ciba® IRGACURE® 1800 also from Ciba Specialty Chemicals, Inc.); 2-hydroxy-2-methyl-1-phenyl-propan-1-one (Ciba® DAROCUR® 1173 also from Ciba Specialty Chemicals, Inc.); 2-benzyl-2-dimethylamino-1-(4-morpholinophenyl)-butanone-1 (Ciba® IRGACURE® 369 also from Ciba Specialty Cheimcals, Inc.); 2-methyl-1[4-(methylthio)phenyl]-2-morpholinopropan-1-one (Ciba® IRGACURE® 907 also from Ciba Specialty Cheimcals, Inc.); a combination of 50% 2,4,6-trimethylbenzoyl-diphenyl-phosphineoxide and 50% 2-hydroxy-2-methyl-1-phenyl-propan-1-one (Ciba® DAROCUR® 4265 also from Ciba Specialty Cheimcals, Inc.); and 1-hydroxy-cyclohexyl-phenyl-ketone (CHIVACURE® 184B, available from Chitec Chemical Company of Taipei Hsien, 235, Taiwan, R.O.C.); and combinations thereof.

Optional Components

The curable (meth)acrylate formulation may further comprise an optional component. Examples of such optional components include, but are not limited to, (c) an antioxidant, (d) a fluorescent dye, (e) a reactive diluent, (f) a light stabilizer, (g) a photosensitizer, (h) a wetting agent, (i) a silane, and (j) a UV absorber.

Component (c) Antioxidant

Component (c) is an antioxidant that may be optionally added to the curable (meth)acrylate formulation. The amount of component (c) may be up to 1% based on the weight of the curable (meth)acrylate formulation. Suitable antioxidants are known in the art and commercially available. Suitable antioxidants include phenolic antioxidants and combinations of phenolic antioxidants with stabilizers. Phenolic antioxidants include fully sterically hindered phenols and partially hindered phenols. Stabilizers include organophosphorous derivatives such as trivalent organophosphorous compound, phosphites, phosphonates, and a combination thereof; thiosynergists such as organosulfur compounds including sulfides, dialkyldithiocarbamate, dithiodipropionates, and a combination thereof; and sterically hindered amines such as tetramethyl-piperidine derivatives. Suitable antioxidants and stabilizers are disclosed in Zweifel, Hans, “Effect of Stabilization of Polypropylene During Processing and Its Influence on Long-Term Behavior under Thermal Stress,” Polymer Durability, Ciba-Geigy AG, Additives Division, CH-4002, Basel, Switzerland, American Chemical Society, vol. 25, pp. 375-396, 1996.

Suitable phenolic antioxidants include vitamin E and IRGANOX® 1010 also from Ciba Specialty Chemicals, Inc. IRGANOX® 1010 comprises pentaerythriol tetrakis(3-(3,5-di-t-butyl-4-hydroxyphenyl)propionate).

The curable (meth)acrylate formulation may comprise: 90 to 99.5% component (a), 0.5 to 10% component (b), and 0 to 1% component (c).

Component (d) is a fluorescent dye that may optionally be added to the curable (meth)acrylate formulation. Examples of fluorescent dyes include but are not limited to rhodamine 6G, 2,2′-(2,5 thiophenediyl)bis-[(tert)butylbenzoxazole] UVITEX OB from Ciba Specialty Chemicals, Inc. of Tarrytown, N.Y. 10591, U.S.A. The amount of component (d) used may be 0 to 1% based on the total amount of curable (meth)acrylate formulation.

Component (e) is a reactive diluent that does not contain a (meth)acrylate. The choice of component (e) is governed by many factors such as the solubility and miscibility of the components in the curable (meth)acrylate formulation, the method of using the curable (meth)acrylate formulation, and safety and environmental regulations. Examples of suitable reactive diluents include, but are not limited to, maleic anhydrides, vinyl acetates, vinyl ester, vinyl ethers, fluoro alkyl vinyl ethers, vinyl pyrrolidones such as N-vinyl pyrrolidone, styrene, and combinations thereof. Examples of suitable vinyl ethers include, but are not limited to butanediol divinyl ether, cyclohexanedimethanol divinyl ether, cyclohexanedimethanol monovinyl ether, cyclohexyl vinyl ether, diethyleneglycol divinyl ether, diethyleneglycol monovinyl ether, dodecyl vinyl ether, ethyl vinyl ether, hydroxybutyl vinyl ether, isobutyl vinyl ether, isopropyl vinyl ether, n-butyl vinyl ether, n-propyl vinyl ether, octadecyl vinyl ether, triethyleneglycol divinyl ether, and combinations thereof. Vinyl ethers are known in the art and commercially available from BASF AG of Germany. The amount of component (e) used may be 0 to 1% based on the total amount of curable (meth)acrylate formulation.

Component (f)

Component (f) is a light stabilizer that may optionally be added to the curable (meth)acrylate formulation. Examples of suitable light stabilizers include, but are not limited to, decanedioic acid, bis(2,2,6,6-tetramethyl-1-(octyloxy)-4-piperidinyl) ester, reaction products with 1,1-dimethylethylhydroperoxide and octane, which is commercially available as Ciba® TINUVIN® 123 from Ciba Specialty Chemicals, Inc. of Tarrytown, N.Y. 10591, U.S.A. The amount of component (f) used may be 0 to 1% based on the total amount of curable (meth)acrylate formulation.

Component (g)

Component (g) photosensitizer that may optionally be added to the curable (meth)acrylate formulation in addition to or instead of component (b). Component (g) changes the wavelength of radiation required to cure the curable (meth)acrylate formulation. One skilled in the art would be able to select appropriate photosensitizers without undue experimentation based on the specific (meth)acrylates and fluorofunctional (meth)acrylates selected for component (a). Component (g) may comprise a ketone, coumarin dye, xanthene dye, acridine dye, thiazole dye, thiazine dye, oxazine dye, azine dye, aminoketone dye, porphyrin, aromatic polycyclic hydrocarbon, p-substituted aminostyryl ketone compound, aminotriaryl methane, merocyanine, squarylium dye, pyridinium dye, or combination thereof. Examples of component (g) include, but are not limited to rose bengal, camphorquinone, glyoxal, biacetyl, 3,3,6,6-tetramethylcyclohexanedione, 3,3,7,7-tetramethyl-1,2-cycloheptanedione, 3,3,8,8-tetramethyl-1,2-cyclooctanedione, 3,3,18,18-tetramethyl-1,2-cyclooctadecanedione, dipivaloyl, benzil, furil, hydroxybenzil, 2,3-butanedione, 2,3-pentanedione, 2,3-hexanedione, 3,4-hexanedione, 2,3-heptanedione, 3,4-heptanedione, 2,3-octanedione, 4,5-octanedione, 1,2-cyclohexanedione, 2-isopropylthioxanthone, benzophenone, or combination thereof. Alternatively, component (g) may comprise 2-isopropylthioxanthone or benzophenone or a combination thereoL The amount of component (g) used may be 0 to 2%, alternatively 0.01 to 2%, and alternatively 0.05 to 0.5% based on the total amount of curable (meth)acrylate formulation.

Component (h)

Component (h) is a wetting agent that may optionally be added to the curable (meth)acrylate formulation. Examples of component (h) include, but are not limited to silicone diacrylate, which is commercially available as EBECRYL® 350 from UCB Chemicals of Belgium; silicone hexaacrylate, which is commercially available as EBECRYL® 1360 also from UCB Chemicals; polyether modified polydimethylsiloxanes, which are commercially available as BYK®-307, BYK®-UV 3510, and BYK®-333 from BYK-Chemie GmbH of Germany; polyether modified acryl functional polydimethylsiloxane, which is commercially available as BYK®-UV 3500, also from BYK-Chemie GmbH; and polyacrylic copolymer, which is commercially available as BYK®-381 also from BYK-Chemie GmbH; crosslinkable silicone acrylates, which are commercially available as Rad 2100, Rad 2500, Rad 2600, and Rad 2700 from Tego Chemie Service GmbH of Germany; and crosslinkable silicone polyether acrylates, which are commercially available as Rad 2200 N, Rad 2250, and Rad 2300 also from Tego Chemie Service GmbH. The amount of component (h) used may be 0 to 1% based on the total amount of curable (meth)acrylate formulation.

Component (i)

Component (i) is an silane that may optionally be added to the curable (meth)acrylate formulation. Examples of component (i) include, but are not limited to alkoxysilanes such as glycidoxypropyltriethoxysilane, glycidoxypropyltrimethoxysilane, methacryloxypropyltriethoxysilane, methacryloxypropyltrimethoxysilane, tetraethoxysilane, tetramethoxysilane, vinyltriethoxysilane, vinyltrimethoxysilane, and combinations thereof. The amount of component (i) used may be 0 to 2% based on the total amount of curable (meth)acrylate formulation.

Component (j)

Component (j) is a UV absorber that may optionally be added to the curable (meth)acrylate formulation for extending visible lifetime. Examples of component (j) include, but are not limited to 1-methoxy-2-propanol and 1,3-benzenediol, 4-[4,6-bis(2,4-dimethylphenyl)-1,3,5-triazin-2-yl]-reaction products with [(dodecyloxy)methyl]oxirane and oxirane mono[(C10-16 alkyloxy)methyl derivatives, which is commercially available as TINUVIN® 400 from Ciba Specialty Chemicals, Inc. of Tarrytown, N.Y. 10591, U.S.A. The amount of component (j) used may be 0 to 1% based on the total amount of curable (meth)acrylate formulation.

Molding Method

This invention relates to a molding method. This invention may be used in various lithography techniques, such as soft lithography techniques. In soft lithography, a mold may be prepared by replica molding, in which a curable silicone composition is cast against a master that has a patterned relief structure on its surface. An example of a curable silicone composition suitable for this purpose is SYLGARD® 184, which is commercially available from Dow Corning Corporation of Midland, Michigan, U.S.A. The curable silicone composition is then cured and removed from the master. The resulting product is a silicone mold having a patterned surface.

The method of this invention comprises:

A) filling a silicone mold having a patterned surface with a curable (meth)acrylate formulation, described above;

B) curing the curable (meth)acrylate formulation to form a patterned feature;

C) separating the silicone mold and the patterned feature;

optionally D) etching the patterned feature; and

optionally E) repeating steps A) to D) reusing the silicone mold.

The method may optionally further comprise:

I) casting a curable silicone composition against a master,

II) curing the curable silicone composition to form the silicone mold, and

III) removing the silicone mold from the master before step A).

Step A) may be performed by various methods. For example, step A) may be performed by contacting the patterned surface of the silicone mold with a substrate, such that patterned structures in the patterned surface form a network of empty channels. When the curable (meth)acrylate formulation is placed at open ends of the network, capillary action fills the channels with the curable (meth)acrylate formulation. Alternatively, the curable (meth)acrylate formulation may be applied to the patterned surface before contacting the patterned surface with a substrate. Alternatively, the curable (meth)acrylate formulation may be applied to a surface of a substrate before the patterned surface is contacted with the substrate. Alternatively, the mold may be sprayed with some or all of the fluorofunctional (meth)acrylate before the remaining components of the curable (meth)acrylate formulation are combined and filled in the silicone mold. Alternatively, the mold may be sprayed with a fluorofunctional surfactant before the curable (meth)acrylate formulation is filled in the silicone mold.

Step B) may be performed by exposing the curable (meth)acrylate formulation to UV radiation, by heating the curable (meth)acrylate formulation, or a combination thereof. The exposure dose depends on the specific curable (meth)acrylate formulation selected and the configuration of the mold, however, exposure may be 100 milliJoule to 4000 milliJoule. The temperature to which the composition is heated also depends on the specific (meth)acrylate formulation selected, however the temperature may be 50° C. to 200° C., alternatively 100° C. to 120° C.

Step C) may be performed by any convenient means such as removing the silicone mold from the patterned feature by, for example, manually peeling the silicone mold off the patterned feature or automatically using, for example, a micromolding tool from SUSS MicroTec, Inc. of Indianapolis, Ind. 46204, U.S.A.

Step D) may be performed by techniques known in the art, for example, reactive ion etching or wet etching. In some lithography techniques, such as imprint molding, solid may form on a substrate in undesired areas during step B). Etching may be used to remove this excess solid, or to remove layers under the excess solid, or both.

This invention may be used in various lithography techniques. Examples of such lithography techniques include, but are not limited to, imprint molding, step and flash imprint molding, solvent assisted micromolding (SAMIM), microtransfer molding, and micromolding in capillaries (MIMIC).

This invention may be used for imprint molding. In this lithography technique, the curable (meth)acrylate formulation is applied on a surface of a substrate. The patterned surface of the silicone mold is brought into contact with the surface of the substrate, thereby distributing the curable (meth)acrylate formulation in the silicone mold. The curable (meth)acrylate formulation is then cured to a solid, and the silicone mold is removed. Imprint molding may be used to prepare, for example, photodetectors and quantum-wire, quantum-dot, and ring transistors.

This invention may also be used in SAMIM. In this lithography technique, the curable (meth)acrylate formulation is applied on a surface of a substrate. A patterned surface of a silicone mold is wetted with a solvent and is brought into contact with the surface of the curable (meth)acrylate formulation. The choice of solvent depends on various factors including the specific silicone mold and curable (meth)acrylate formulation selected; the solvent should rapidly dissolve or swell the surface of the curable (meth)acrylate formulation but not swell the silicone mold. The curable (meth)acrylate formulation is then cured to a solid, and the silicone mold is removed.

This invention may be used in microtransfer molding, in which a curable (meth)acrylate formulation described above is applied to the patterned surface of the silicone mold. If any excess curable (meth)acrylate formulation is present, it may be removed, for example, by scraping with a flat block or by blowing with stream of inert gas. The resulting filled mold may be contacted with a substrate. The curable (meth)acrylate formulation is then cured by heating, exposure to UV radiation, or a combination thereof. When the curable (meth)acrylate formulation has cured to a solid, the mold may be peeled away to leave a patterned feature on the substrate. Microtransfer molding may be used to fabricate, for example, optical waveguides, couplers, and interferometers.

This invention may also be used for MIMIC. In this lithography technique, the patterned surface of the silicone mold is contacted with a surface of a substrate. The patterned structures in the silicone mold form a network of empty channels. When the curable (meth)acrylate formulation described above is placed at open ends of the network, capillary action fills the channels with the curable (meth)acrylate formulation. The curable (meth)acrylate formulation is then cured to a solid, and the silicone mold is removed.

The method may be used to prepare a resist layer or a permanent layer in a lithography technique selected from the group consisting of imprint molding, step and flash imprint molding, solvent assisted micromolding, microtransfer molding, and micromolding in capillaries. This invention may be used during fabrication of various devices, including but not limited to light emitting diodes, including but not limited to organic light emitting diodes; transistors such as organic field effect transistors and thin film transistors; display devices such as plasma displays and liquid crystal displays, photodetectors, optical waveguides, couplers, and interferometers.

### EXAMPLES

These examples are intended to illustrate the invention to one of ordinary skill in the art and should not be interpreted as limiting the scope of the invention set forth in the claims.

### Reference Example 1

### Sample Preparation and Evaluation

The formulations are mixed in a Hauschild mixer by adding the amounts of components as defined in the examples below.

Viscosity is measured with Cannon-Fenske routine (Ubbelohde) viscometer tubes from International Research Glassware, Kenilworth, N.J., 07033 U.S.A. The method for viscosity measurement is according to ASTM D 445 and ISO 3104. Specifications conform to ASTM D 446 and ISO 3105.

The cure studies on thick films are performed on a Fusion curing processor (300 or 600 Watt lamps). In the Fusion curing processor, a coating of the formulation is applied to one of the following substrates: glass slide, silicon wafer, glass wafer, or plastic such as acrylic substrate. The coating is applied manually or by using a roll coater. The substrate is conveyed through the Fusion curing processor at a fixed line speed, and adjusting belt speeds controlled cure energy. An IL 1350 radiometer/photometer (from International Lights) is used to monitor the UV light flux at the sample. The extent of cure is measured by observing surface tack (dry to touch) immediately after UV light curing. Through cure is evaluated by removing the cured film from the substrate and evaluating tack at the bottom.

For thin films UV cure studies are performed as per the following procedures. The formulation can be cured both in air (under PDMS mold) and in Argon atmosphere (either under PDMS mold or without PDMS mold) to ensure absence of any oxygen inhibition effects.

Inert Atmosphere

The formulation and substrates are transported in an Ar glove box first. The formulation is dispersed on a substrate by spin coating. A spin speed of 500-2000 rpm is used to spread the formulation. The resulting film is transferred into a container and sealed under vacuum for taking to the UV cure tool, either with a PDMS or without a PDMS mold on top of the film. The UV exposure tool has N₂ knife edge for help purging O₂. The film surface is covered with a cover glass to prevent contamination with particles. The UV exposure is set around 500 mJ/cm². After the UV cure, the film is sent back to the Argon glove box for further thermal cure at 120° C. for two minute to increase cross-linking density. After cure, the PDMS mold is released from the cured acrylate film surface. A pattern transfer from the PDMS mold onto the cured acrylate film surface is observed using visual inspection, optical microscopy, and electron microscopy.

Air Atmosphere

The formulation is dispensed on a substrate by spin coating or doctor blade drawdown technique. In spin coating, a spin speed of 500-2000 rpm is used to spread the formulation into a film. After spin coating, a SYLGARD® 184 PDMS mold is placed on top of the film. The film with the mold is sent to the UV cure tool for curing. After UV cure, the mold is released from the cured film. A pattern transfer is accomplished from the mold surface to the film surface. The film under the PDMS mold is cured and the area not under PDMS mold was not cured. A pattern transfer from the PDMS mold onto the cured film surface is observed using visual inspection, optical microscopy, and electron microscopy.

### Comparative Example 1

A curable (meth)acrylate formulation is prepared by mixing the following components.

| Component | Parts by weight |
|---|---|
| 2-ethylhexyl acrylate | 50 |
| 1,6 hexanediol diacrylate | 30 |
| trimethylolpropane triacrylate | 15 |
| DAROCUR ® 1173 | 5 |

The formulation is cured under UV exposure as described in Reference Example 1. However, the cured film sticks to a SYLGARD® 184 PDMS mold. No pattern transfer is accomplished.

### Comparative Example 2

A curable (meth)acrylate formulation is prepared by mixing the following components.

| Component | Parts by weight |
|---|---|
| Tetrahydrofuryl methacrylate | 50 |
| 1,6 hexanediol diacrylate | 30 |
| trimethylolpropane triacrylate | 15 |
| DAROCUR ® 1173 | 5 |

The formulation is cured under UV exposure as described in Reference Example 1. The formulation is cured under UV exposure. However, the cured film sticks to a SYLGARD® 184 PDMS mold. No pattern transfer is accomplished.

### Example 1

A curable (meth)acrylate formulation is prepared by mixing the following components

| Component | Parts by weight |
|---|---|
| 1,4 butanediol diacrylate | 30 |
| 2-ethoxyethyl acrylate | 13 |
| ethoxylated (9) trimethylolpropane triacrylate | 25 |
| isobutyl acrylate | 15 |
| octafluoropentyl acrylate | 8 |
| IRGACURE ® 819 | 3 |
| pentaerythritol tetraacrylate | 6 |

### Example 2

A curable (meth)acrylate formulation is prepared by mixing the following components

| Component | Parts by weight |
|---|---|
| 1,4 butanediol diacrylate | 50 |
| isobutyl acrylate | 10 |
| propoxylated (6) trimethylolpropane triacrylate | 20 |
| hydroxyethyl acrylate | 10 |
| 2,2,2 trifluoroethyl methacrylate | 7 |
| IRGACURE ® 1800 | 3 |

### Example 3

A curable (meth)acrylate formulation is prepared by mixing the following components.

| Component | Parts by weight |
|---|---|
| 1,4 butanediol diacrylate | 30 |
| 2-ethoxyethyl acrylate | 13 |
| ethoxylated (9) trimethylolpropane triacrylate | 25 |
| isobutyl acrylate | 15 |
| octafluoropentyl acrylate | 8 |
| IRGACURE ® 1800 | 3 |
| pentaerythritol tetraacrylate | 6 |

### Example 4

A curable (meth)acrylate formulation is prepared by mixing the following components.

| Component | Parts by weight |
|---|---|
| 2-ethoxyethyl methacrylate | 6 |
| 1,4-butanediol diacrylate | 22 |
| isobornyl acrylate | 14 |
| dipropylene glycol diacrylate | 38 |
| trimethylolpropane triacrylate | 12 |
| 2,2,2 trifluoroethyl methacrylate | 8 |
| CHIVACURE 184B | 1 |
| TINUVIN ® 123 | 0.4 |

### Example 5

A curable (meth)acrylate formulation is prepared by mixing the following components.

| Component | Parts by weight |
|---|---|
| 1,6-hexanediol diacrylate | 40 |
| 2-ethoxyethyl acrylate | 15 |
| ethoxylated (9) trimethylolpropane triacrylate | 30 |
| isobutyl acrylate | 5 |
| octafluoropentyl acrylate | 5 |
| IRGACURE ® 1800 | 5 |

### Example 6

A curable (meth)acrylate formulation is prepared by mixing the following components.

| Component | Parts by weight |
|---|---|
| 1,6-hexanediol diacrylate | 40 |
| 2-ethoxyethyl acrylate | 15 |
| ethoxylated (9) trimethylolpropane triacrylate | 30 |
| isobutyl acrylate | 5 |
| octafluoropentyl acrylate | 5 |
| IRGACURE ® 1800 | 5 |

### Example 7

A curable (meth)acrylate formulation is prepared by mixing the following components.

| Component | Parts by weight |
|---|---|
| 2-ethoxyethyl methacrylate | 11 |
| 1,4-butanediol diacrylate | 50 |
| N-vinyl pyrrolidone | 13 |
| polyethylene glycol (200) diacrylate | 11 |
| trimethylolpropane triacrylate | 13 |
| 2,2,2 trifluoroethyl methacrylate | 8 |
| CHIVACURE 184B | 1 |
| TINUVIN ® 123 | 0.4 |

### Example 8

A curable (meth)acrylate formulation is prepared by mixing the following components.

| Component | Parts by weight |
|---|---|
| 1,3-butylene glycol diacrylate | 45 |
| 2-ethoxyethyl acrylate | 15 |
| ethoxylated (20) trimethylolpropane triacrylate | 25 |
| pentaerythritol tetraacrylate | 5 |
| octafluoropentyl acrylate | 5 |
| IRGACURE ® 184 | 5 |

### Examples 9-12

Curable (meth)acrylate formulations are prepared by mixing the components in the amounts shown in the table.

| | Example | | | |
|---|---|---|---|---|
| | 9 | 10 | 11 | 12 |
| | Parts by | Parts by | Parts by | Parts by |
| Component | weight | weight | weight | weight |
| 1,4-butanediol diacrylate | 21.5 | 21.5 | 21.5 | 21.5 |
| dipropyleneglycol diacrylate | 36.2 | 36.2 | 36.2 | 36.2 |
| isobornyl acrylate | 13.4 | 13.4 | 13.4 | 13.4 |
| 2-ethoxyethyl acrylate | 5.7 | 5.7 | 5.7 | 5.7 |
| trimethylolpropane triacrylate | 10.6 | 10.6 | 10.6 | 10.6 |
| 2,2,2 trifluoroethyl methacrylate | 7.6 | 7.6 | 7.6 | 7.6 |
| CHIVACURE 184 | 3.0 | | | |
| IRGACURE ® 1800 | 2.0 | | | |
| IRGACURE ® 907 | | 4.5 | | |
| Isopropylthioxanthone (ITX) | | 0.5 | | |
| DAROCUR ® 4265 | | | 5.0 | |
| IRGACURE ® 369 | | | | 5.0 |

### Examples 13 and 14

Amounts in the table of 1,4-butanediol diacrylate, dipropyleneglycol diacrylate, isobornyl acrylate, ethoxyethoxyethylacrylate, trimethylolpropane triacrylate, tetraethoxysilane, and methacryloxypropyltrimethoxysilane are mixed for 30 minutes. Acrylic acid in the amount in the table is added, and the resulting composition is mixed for another 30 minutes. Water in the amount in the table is added, and the resulting composition is mixed for 60 minutes. The resulting composition is stripped at 70° C. under reduced pressure to produce a composition containing resin formed in situ.

| Component | Parts by weight |
|---|---|
| 1,4-butanediol diacrylate | 18 |
| dipropyleneglycol diacrylate | 30 |
| isobornyl acrylate | 11 |
| ethoxyethoxyethyl acrylate | 5 |
| trimethylolpropane triacrylate | 9 |
| tetraethoxysilane | 13 |
| methacryloxypropyltrimethoxysilane | 8 |
| acrylic acid | 4 |
| water | 2 |

Curable (meth)acrylate formulations are prepared by mixing the components in the amounts shown in the table below.

| | Example | |
|---|---|---|
| | 13 | 14 |
| Component | Parts by weight | Parts by weight |
| Composition containing resin | 27.3 | 27.3 |
| 2,2,2 trifluoroethyl methacrylate | 2.4 | 2.4 |
| IRGACURE ® 819 | 0.3 | |
| IRGACURE ® 184 | | 0.3 |

### Examples 15 and 16

Amounts in the table of pentaerythritol tetraacrylate and acrylic acid are mixed for 30 minutes. Water in the amount in the table is added, and the resulting composition is mixed for 60 minutes. The resulting composition is stripped at 70° C. under reduced pressure to produce a composition containing resin formed in situ.

| Component | Parts by weight |
|---|---|
| peentaerythritol tetraacrylate | 73 |
| tetraethoxysilane | 13 |
| methacryloxypropyltrimethoxysilane | 8 |
| acrylic acid | 4 |
| water | 2 |

Curable (meth)acrylate formulations are prepared by mixing the components in the amounts shown in the table below.

| | Example | |
|---|---|---|
| | 15 | 16 |
| Component | Parts by weight | Parts by weight |
| Composition containing resin | 27.3 | 27.3 |
| 2,2,2 trifluoroethylmethacrylate | 2.4 | 2.4 |
| IRGACURE ® 819 | 0.3 | |
| IRGACURE ® 184 | | 0.3 |

### INDUSTRIAL APPLICABILITY

The curable (meth)acrylate formulations used in these examples demonstrate pattern resolution and mold release properties. Without wishing to be bound by theory, it is thought that transfer of monomers from the curable (meth)acrylate formulation to the mold is minimized by the presence of the fluorofunctional (meth)acrylate, and this increases mold life by decreasing mold fouling and swelling of the mold. This process may provide a lower cost alternative to photolithographic methods for providing a patterned coating or resist by increasing throughput, decreasing process time, or both.

1. A method comprising:
A) filling a silicone mold having a patterned surface with a curable (meth)acrylate formulation, where the curable (meth)acrylate formulation comprises (a) fluorofunctional (meth)acrylate or a combination of a fluorofunctional (meth)acrylate and a (meth)acrylate, (b) a photoinitiator, optionally (c) an antioxidant, optionally (d) a fluorescent dye, optionally (e) a reactive diluent, optionally (f) a light stabilizer, optionally (g) a photosensitizer, optionally (h) a wetting agent, and optionally (j) an ultra-violet radiation absorber;
B) curing the curable (meth)acrylate formulation to form a patterned feature;
C) separating the silicone mold and the patterned feature;
optionally D) etching the patterned feature; and
optionally E) repeating steps A) to D) reusing the silicone mold.

2. The method of claim 1, where the fluorofunctional (meth)acrylate comprises heptadecafluorodecyl acrylate, octafluoropentyl acrylate, octafluoropentyl methacrylate, tetrafluopropyl acrylate, trifluoroethyl acrylate, trifluoroethyl methacrylate, or a combination thereof.

3. The method of claim 1 or claim 2, where the (meth)acrylate is present and is selected from the group consisting of 2(2-ethoxyethoxy)ethyl acrylate, 2-acryloylethyl-2-hydroxyethyl-o-phthalate, 2-ethoxyethoxyethyl acrylate, 2-ethoxyethyl acrylate, 2-ethoxyethylmethacrylate, 2-ethylhexyl methacrylate, 2-hydroxyethyl acrylate, 2-hydroxyethyl methacrylate, 2-hydroxypropyl acrylate, 2-hydroxypropyl methacrylate, 2-methoxyethyl acrylate, 2-phenoxyethyl acrylate, 4-hydroxybutyl acrylate, acrylic acid, alkoxylated lauryl acrylate, alkoxylated phenol acrylate, alkoxylated tetrahydrofurfuryl acrylate, allyl methacrylate, benzyl acrylate, benzyl methacrylate, beta carboxy ethyl acrylate, butyl diglycol methacrylate, caprolactone acrylate, cetyl acrylate, cyclic trimethylolpropane formal acrylate, cyclohexyl acrylate, cyclohexyl methacrylate, cyclohexylmethacrylate, dicyclopentadienyl methacrylate, diethylaminoethyl methacrylate, dimethyl aminoethyl acrylate, dimethyl aminoethyl methacrylate, dimethyl aminoethyl methacrylate methylchloride salt, EO7 ethyl capped methacrylate, epoxy acrylate, ethoxyethyl methacrylate, ethoxylated (10) hydroxyethyl methacrylate, ethoxylated (2) hydroxyethyl methacrylate, ethoxylated (5) hydroxyethyl methacrylate, ethoxylated phenol acrylate, ethyl methacrylate, ethyl triglycol methacrylate, glycidyl methacrylate, hydroxyethyl acrylate, isobornyl acrylate, isobornyl methacrylate, isobutyl acrylate, isobutyl methacrylate, isodecyl acrylate, isooctyl acrylate, lauryl acrylate, lauryl methacrylate, lauryl tridecyl acrylate, methacrylic acid, methacrylonitrile, methoxy polyethylene glycol (350) monoacrylate E06, methyl methacrylate, n-butyl methacrylate, octyl decyl acrylate, polypropylene glycol monomethacrylate, propoxylated (2) allyl methacrylate, stearyl acrylate, stearyl methacrylate, tert-butyl amino methacrylate, tert-butyl acrylate, tert-butyl methacrylate, tetrahydrofurfuryl acrylate, tetrahydrofurfuryl methacrylate, tetrahydrofuryl acrylate, tetrahydrofuryl methacrylate, tetrahydrogenfuranmethacrylate, tridecyl acrylate, tridecyl methacrylate, trimethylcyclohexylmethacrylate, urethane acrylate, 1,12-dodecandiol dimethacrylate, 1,3-butandiol dimethacrylate, 1,3-butylene glycol diacrylate, 1,3-butylene glycol dimethacrylate, 1,4-butanediol diacrylate, 1,4 butanediol dimethacrylate, 1,6-hexanediol diacrylate, 1,6-hexanediol dimethacrylate, alkoxylated aliphatic diacrylate, aliphatic dimethacrylate, bisphenol A diacrylate, bisphenol A ethoxylate dimethacrylate, butanediol dimethacrylate, diethylene glycol diacrylate, diethylene glycol dimethacrylate, dipropylene glycol diacrylate, dipropylene glycol dimethacrylate, ethoxylated bisphenol-A diacrylate, ethylene glycol dimethacylate, neopentyl glycol diacrylate, polyethylene glycol 200 diacrylate, polyethylene glycol 200 dimethacrylate, polypropylene glycol 400 dimethacrylate, propoxylated (2) neopentyl glycol diacrylate, tetraethylene glycol diacrylate, tetraethylene glycol dimethacrylate, tricyclodecane dimethanol diacrylate, triethylene glycol dimethacrylate, tripropylene glycol diacrylate, ethoxylated trimethylol propane triacrylate, glycelyl propoxy triacrylate, pentaerythritol triacrylate, propoxylated glycerol triacrylate, propoxylated trimethylolpropane triacrylate, triacrylate ester, trimethacrylate ester, trimethylol propane triacrylate, trimethylol propane trimethacrylate, trimethylolpropane ethoxy triacrylate, tetrafunctional acrylate, acrylate ester of pentaerythritol, pentaerythritol tetraacrylate, dipentaerythritol pentaacrylate, ditrimethylolpropane tetraacrylate, ethoxylated pentaerythritol tetraacrylate, caprolactone modified dipentaerythritol hexaacrylate, caprolactone modified dipentaerythritol hexamethacrylate and combinations thereof.

4. The method of any one of the preceding claims where component (b) comprises: alpha-hydroxy ketone; phenylglyoxylate; benzildimethyl-ketal; alpha-aminoketone; mono acyl phosphine; bis acyl phosphine; benzoin ether; benzoin isobutyl ether; benzoin isopropyl ether; benzophenone; benzoylbenzoic acid; methyl benzoylbenzoate; 4-benzoyl-4′-methyldiphenyl sulfide; benzylmethylketal; 2-n-butoxyethyl-4-dimethylaminobenzoate; 2-chlorothioxanthone; 2,4-diethylthioxanthanone; 1-hydroxy-cyclohexyl-phenyl-ketone, methylbenzoylformate; phenyl bis(2,4,6-trimethyl benzoyl)- phosphine oxide; a combination of bis(2,6-dimethoxybenzoyl)-2,4,4-trimethyl-pentylphosphineoxide and 1-hydroxy-cyclohexyl-phenyl-ketone; 2-hydroxy-2-methyl-1-phenyl-propan-1-one; 1-hydroxy-cyclohexyl-phenyl-ketone; 2-benzyl-2-dimethylamino-1-(4-morpholinophenyl)-butanone-1; 2-methyl-1[4-(methylthio)phenyl]-2-morpholinopropan-1-one; a combination of 50% 2,4,6-trimethylbenzoyl-diphenyl-phosphineoxide and 50% 2-hydroxy-2-methyl-1-phenyl-propan-1-one; or a combination thereof.

5. The method of any one of the preceding claims, where at least one optional component is present and component (c) comprises a phenolic antioxidant or a combination of a phenolic antioxidant and a stabilizer; component (d) comprises rhodamine 6G, 2,2′-(2,5-thiophendiyl)bis[(tert)-butylbenzoxazole], or a combination thereof; component (e) comprises a maleic anhydride, a vinyl acetate, a vinyl ester, a vinyl ether, a fluoro alkyl vinyl ether, a vinyl pyrrolidone, a styrene, or a combination thereof; component (f) comprises decanedioic acid, bis(2,2,6,6-tetramethyl-1-(octyloxy)-4-piperidinyl) ester, reaction products with 1,1-dimethylethylhydroperoxide and octane, or a combination thereof; component (g) comprises a ketone, coumarin dye, xanthene dye, acridine dye, thiazole dye, thiazine dye, oxazine dye, azine dye, aminoketone dye, porphyrin, aromatic polycyclic hydrocarbon, p-substituted aminostyryl ketone compound, aminotriaryl methane, merocyanine, squarylium dye, pyridinium dye, or combination thereof; component (h) comprises silicone diacrylate, silicone hexaacrylate, polyether modified polydimethylsiloxane, polyether modified acryl functional polydimethylsiloxane, polyacrylic copolymer, crosslinkable silicone acrylate, crosslinkable silicone polyether acrylate, or a combination thereof; component (i) comprises glycidoxypropyltriethoxysilane, glycidoxypropyltrimethoxysilane, methacryloxypropyltriethoxysilane, methacryloxypropyltrimethoxysilane, tetraethoxysilane, tetramethoxysilane, vinyltriethoxysilane, vinyltrimethoxysilane, or a combination thereof; and component (j) comprises 1-methoxy-2-propanol and 1,3-benzenediol, 4-[4,6-bis(2,4-dimethylphenyl)-1,3,5-triazin-2-yl]-reaction products with [(dodecyloxy)methyl]oxirane and oxirane mono[(C10-16 alkyloxy)methyl derivatives.

6. The method of any one of the preceding claims, further comprising:
I) casting a curable silicone composition against a master,
II) curing the curable silicone composition to form the silicone mold, and
III) removing the silicone mold from the master before step A).

7. The method of any one of the preceding claims, where the method is used in a lithography technique selected from the group consisting of: imprint molding, step and flash imprint molding, solvent assisted micromolding, microtransfer molding, and micromolding in capillaries.

8. A patterned feature prepared by the method of any one of the preceding claims.

9. The method of any one of claims 1 to 7 used to prepare a resist layer or a permanent layer in a lithography technique selected from the group consisting of imprint molding, step and flash imprint molding, solvent assisted micromolding, microtransfer molding, and micromolding in capillaries.

10. The method of any one of claims 1 to 7 used to prepare a device selected from the group consisting of a display device, a photodetector, a transistor, an optical waveguide, a coupler, an interferometer, and a light emitting diode.
